(19) United States
(12) Patent Application Publication
(10) Pub. No.: US 2014/0360428 A1
(43) Pub. Date: Dec. 11, 2014

(54) RECHARGING APPARATUS

(71) Applicants: So Young JANG, BUSAN (KR); YOUNG HO HONG, SEOUL (KR)

(72) Inventors: So Young JANG, BUSAN (KR); YOUNG HO HONG, SEOUL (KR)

(21) Appl. No.: 14/079,804

(22) Filed: Nov. 14, 2013

(30) Foreign Application Priority Data
Jun. 11, 2013 (KR) 10-2013-0066650

(51) Int. Cl. C30B 15/00

(52) U.S. Cl. CPC C30B 15/002
USPC 117/214; 222/502

(57) ABSTRACT

A recharging apparatus is disclosed. The recharging apparatus includes a body provided with an introduction port and a discharge port, a cover unit including a plurality of divided covers, each of the covers being connected to one end of the body and adapted to rotated about the one end of the body, and an opening and closing adjuster to support one surface of each of the covers and to rotate each of the covers about a portion of each of the covers connected to the one end of the body.

This application claims the benefit of the Korean Patent Application No. 10-2013-0066650, filed on Jun. 11, 2013, which is hereby incorporated by reference as if fully set forth herein.

### BACKGROUND OF THE INVENTION

1. Field of the Invention

The present invention relates to a recharging apparatus for recharging a raw material.

2. Discussion of the Related Art

In general, a single crystal ingot growth apparatus may include a chamber having a space define therein, a crucible installed in the chamber to allow a polycrystalline raw material to be introduced thereinto and melted therein, a heater to heat the crucible to melt the polycrystalline raw material, and a lifting means to submerge a seed crystal in the molten liquid contained in the crucible and gradually lift a growing single crystal ingot.

To facilitate introduction of a raw material into a crucible positioned in a chamber, an apparatus to recharge the raw material is needed. The recharging apparatus is formed in the shape of a vessel provided with an introduction port, a discharge port, and an inner space for storage of a raw material. The discharge port is closed when the space is filled with the raw material, and is opened when the raw material is supplied to the crucible.

The recharging apparatus may be used when the raw material is introduced into the crucible for the first time, and may also be used when the crucible containing the molten liquid is recharged with the raw material.

To supply the raw material to the crucible, the recharging apparatus is lowered by a lifting device to adjoin the crucible in the chamber. In addition, when the recharging apparatus is positioned to adjoin the crucible, the discharge port of the recharging apparatus may be opened, and the stored raw material may be introduced into the crucible. Since the recharging apparatus closely approaches the molten liquid in the crucible for resupply of the raw material, the recharging apparatus may be contaminated by the molten liquid during the recharge process.

### SUMMARY OF THE INVENTION

Embodiments provide a recharging apparatus which is capable of preventing contamination due to molten liquid and damage to constituents around the recharging apparatus.

In one embodiment, a recharging apparatus includes a body provided with an introduction port and a discharge port, a cover unit including a plurality of divided covers, each of the covers being connected to one end of the body and adapted to rotated about the one end of the body, and an opening and closing adjuster to support one surface of each of the covers and to rotate each of the covers about a portion of each of the covers connected to the one end of the body.

The cover unit may be formed in a shape of a plate having an opening at a center thereof, the covers being formed by dividing the plate having the opening at the center thereof into at least two pieces.

An outer circumferential surface of the one end of the body may be provided with a protrusion, and each of the covers is connected to the protrusion.

Each of the covers may include a cover plate provided with an upper surface, a lower surface, a plurality of lateral surfaces positioned between the upper surface and the lower surface, and an extension part protruding from one of the lateral surfaces, and a connection part to connect the extension part to the protrusion.

The connection part may include first to third nuts, a first fixing bolt provided with one end having a first through hole and the other end coupled to a first nut by penetrating the protrusion, a second fixing bolt provided with one end having a second through hole and the other end coupled to a second nut by penetrating the protrusion, and a connection bolt coupled to a third nut by passing through the first through hole, the extension part, and the second through hole, wherein the cover plate rotates about the connection bolt.

A cross section of each of the first fixing bolt and the second fixing bolt penetrating the protrusion may have a shape of a polygon or a cross.

The opening and closing adjuster may include a supporting cone to support one region of the lower surface of each of the cover plates, and a supporter connected to an upper end of the supporting cone, the supporter supporting the supporting cone.

A rotational angle of the cover plates may be adjusted by vertical movement of the supporting cone.

The supporting cone may be provided, at a center thereof, with a groove allowing the supporter to be inserted thereinto, wherein one end of the support inserted into the groove may be coupled to a bottom of the supporting cone.

An outer circumferential surface of the body adjacent to the introduction port may be provided with an interruption projection protruding in a horizontal direction.

The recharging apparatus may further include a guiding part extending in a diametrical direction of the body, having both ends fixed to two different regions of the body adjacent to the introduction port, and provided with a through hole allowing the supporter to be inserted thereinto.

A material to fill the body may be a polycrystalline mass having a diameter ranging from 0.5 mm to 100 mm.

In another embodiment, a recharging apparatus includes a body including an introduction port, a discharge port, and a hollow penetrated portion arranged between the introduction port and the discharge port, a cover unit including a plurality of covers, each of the covers being connected to one end of the body adjacent to the discharge port, and an opening and closing adjuster to support each of the covers and to rotate each of the covers to open and close the discharge port.

When the covers close the discharge port, the covers form a shape of a plate divided into a plurality of pieces and having an opening at a center thereof.

The opening and closing adjuster includes a supporting cone to support one region of a lower surface of each of the covers, and a supporter connected to an upper end of the supporting cone, the supporter supporting the supporting cone.

Each of the covers may be rotated about a portion thereof connected to the body by vertical movement of the supporting cone.

The recharging apparatus may further include a guiding part extending in a diametrical direction of the body, having both ends fixed to two different regions of the body adjacent to the introduction port, and provided with a through hole allowing the supporter to be inserted thereinto.

The guiding part may be formed to be bent, the introduction port may be divided into a first introduction port and a second introduction port by the bent guiding part, and a size of the first introduction port may be different from a size of a second introduction port.

In another embodiment, a growth apparatus includes a chamber provided with a support projection protruding from an inner wall of the chamber in a horizontal direction, a crucible positioned in the chamber, a recharging apparatus to store a raw material and to supplied the stored raw material to the crucible, and a lifting means to vertically move the recharging apparatus within the chamber, wherein the recharging apparatus includes a body including an introduction port, a discharge port, and a stopping projection formed on an outer circumferential surface of the body adjacent to the introduction port and stopped and supported by the support projection, a cover unit including a plurality of divided covers, each of the covers being connected to one end of the body, a supporting cone to support a lower surface of each of the covers, and a supporter having one end connected to an upper end of the supporting cone, and the other end connected to the lifting means.

The covers rotate about one end of the body after the stopping projection of the recharging apparatus is stopped and supported by the support projection of the chamber.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a first perspective view illustrating a recharging apparatus according to an embodiment;

FIG. 2 is a second perspective view illustrating the recharging apparatus shown in FIG. 1;

FIG. 3 is a bottom view illustrating the recharging apparatus shown in FIG. 1;

FIG. 4 is an exploded perspective view illustrating a first cover indicated by a dotted line in FIG. 2;

FIG. 5 is a perspective view illustrating assembly of the first cover shown in FIG. 4;

FIG. 6 is a plan view illustrating a plurality of cover plates shown in FIG. 3;

FIG. 7 is a perspective view illustrating an opening and closing adjuster that supports the cover plates shown in FIG. 3;

FIG. 8 is a cross-sectional view illustrating the cover plates and opening and closing adjuster of FIG. 7, taken along line AB in FIG. 7;

FIG. 9 is an enlarged view illustrating the supporting cone shown in FIG. 7;

FIG. 10 is a cross-sectional view illustrating a typical recharging apparatus;

FIG. 11 is a view illustrating covers according to another embodiment;

FIG. 12 is a view illustrating cover plates of the covers shown in FIG. 11;

FIG. 13 is a perspective view illustrating a recharging apparatus according to another embodiment;

FIG. 14 is a cross-sectional view illustrating a single crystal growth apparatus including a recharging apparatus according to an embodiment; and

FIGS. 15a to 15c are views illustrating filling the crucible with a raw material using a recharging apparatus according to an embodiment.

### DETAILED DESCRIPTION OF THE INVENTION

Embodiments will be clearly understood from the following description taken in conjunction with the accompanying drawings. In the description of embodiments, it will be understood that when a layer (or film), region, pattern or structure is referred to as being “on” another layer (or film), region, pad or pattern, the terminology of “on” and “under” includes both the meanings of “directly” and “indirectly”. Further, the reference about ‘on’ and ‘under’ each layer will be made on the basis of drawings.

It will be appreciated that for simplicity and clarity of illustration, the dimensions of some of the elements are exaggerated, omitted, or schematically shown relative to other elements. In addition, elements shown in the drawings have not necessarily been drawn to scale. Wherever possible, the same reference numbers will be used throughout the drawings to refer to the same or like parts. Hereinafter, a recharging apparatus and a single crystal growth apparatus including the same according to embodiments will be described with reference to the accompanying drawings.

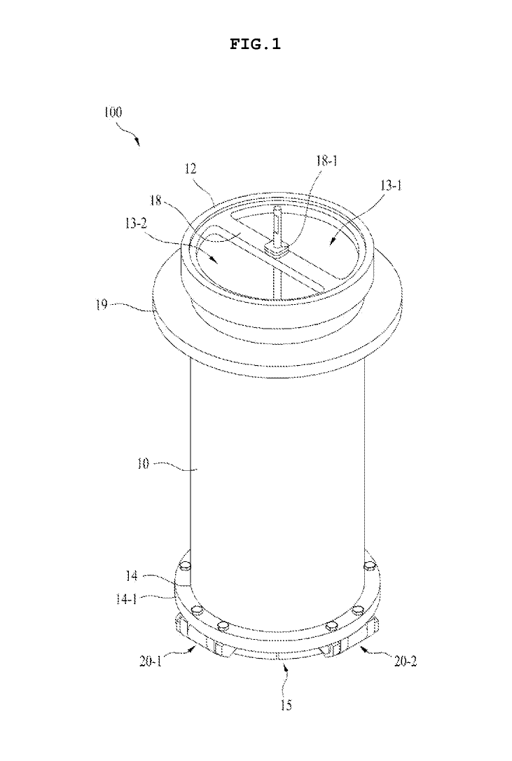

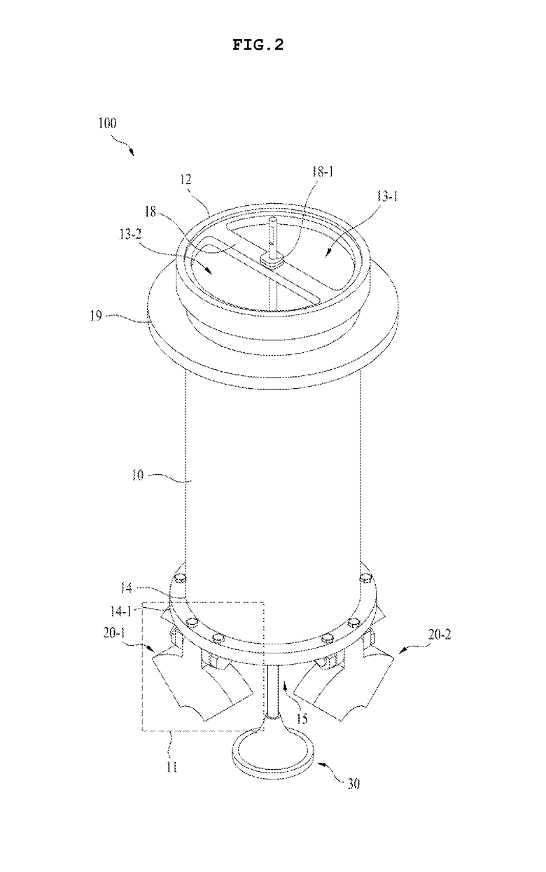

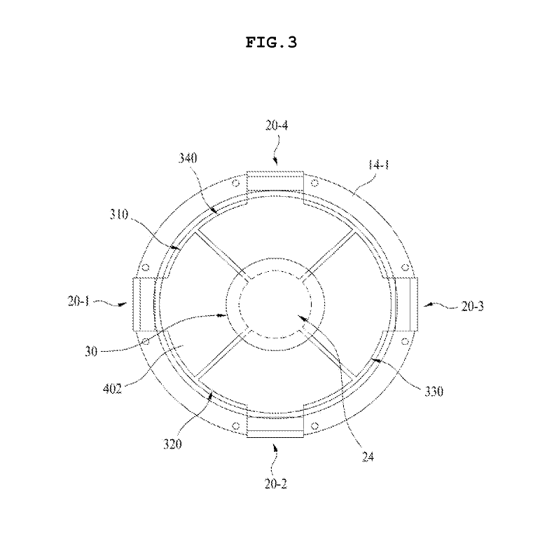

FIG. 1 is a first perspective view illustrating a recharging apparatus 100 according to an embodiment FIG. 2 is a second perspective view illustrating the recharging apparatus 100 shown in FIG. 1, and FIG. 3 is a bottom view illustrating the recharging apparatus 100 shown in FIG. 1.

Referring to FIGS. 1 to 3, the recharging apparatus 100 is a means to fill a vessel (e.g., a crucible), positioned in a reaction chamber (e.g., a chamber for growing a single crystal) with a raw material (e.g., a mass of polysilicon).

The recharging apparatus 100 includes a body 10 provided with introduction ports 131 and 13-2 and a discharge port 15, a cover unit 20 connected to a lower end of the body 10 to cover the discharge port 15, and an opening and closing adjuster 30 to support the cover unit 20 and to adjust the cover unit 20 to open or close the discharge port 15.

The body 10 may be provided with a penetrated portion which is open at both ends 12 and 14, extends in a longitudinal direction, and is hollow. For example, the body 10 may have a shape of a cylindrical pipe or tube, but embodiments are not limited thereto. The body 10 may have any shape that provides a space for storage of a raw material. For example, the cross section of the body 10 may have various shapes including a circle, an ellipse, or a polygon. Herein, the end may refer to an end of one side of the body 10.

The first end 12 of the body 10 may be provided with introduction ports 13-1 and 13-2 for introduction of a raw material therethrough, and the second end 14 may be provided with a discharge port to discharge the introduced raw material. Herein, the first end 12 and the second end 14 may be positioned at opposite sides of the body 10.

Each of the first and second ends 12 and 14 of the body 10 may be cylindrical, but embodiments are not limited thereto. Depending upon the shape of the body 10, they may be formed to be circular, elliptical, or polygonal.

The body 10 extends in a diametrical direction, and may be provided with a guiding part 18, both ends of which are fixed to two different sections of the first end 12.

The first end 12 of the body 10 may be provided with two introduction ports 13-1 and 13-2, which may be divided into a first introduction port 13-1 and a second introduction port 13-2 by the guiding part 18. Herein, the diametrical direction of the body 10 may be perpendicular to the longitudinal direction of the body 10.

The guiding part 18 may have a shape of a plate or a bar. One end thereof may be connected to one section of the first end 12, and the other end of the first end 12 may be connected to another section. The guiding part 18 may be provided with a through-hole 18-1 formed between one end and the other end of the guiding part 18 to allow a supporter 34 of the opening and closing adjuster 30 to be inserted thereinto.

For example, the through-hole 18-1 may be formed at the center of the guiding part 18. The through-hole 18-1 may be aligned with the center of the opening 24 of a cover unit 20, which will be described later.

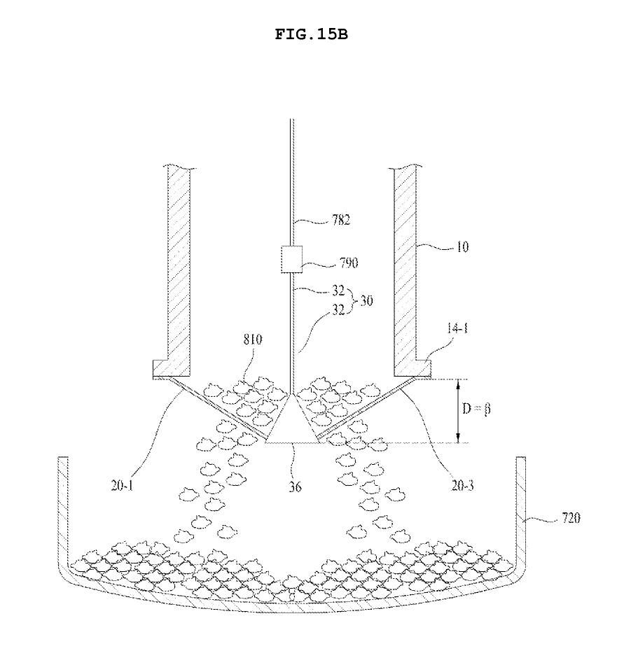

A stopping projection 19 may be formed on the outer circumferential surface of the body 10 adjacent to the first end 12. The stopping projection 19 may be formed in the shape of a ring horizontally protruding from the upper outer circumferential surface of the body 10, but embodiments are not limited thereto. In other embodiments, a plurality of stopping projections spaced apart from each other may be provided. The stopping projection 19 may be hung on and supported by a support projection 701 (see FIG. 14) provided in the chamber, which will be described later.

The outer circumferential surface of the second end 14 of the body 10 may be provided with a protrusion 14-1. The protrusion 14-1 may be formed to protrude from the outer circumferential surface of the body 10 outward of the body 10. For example, the protrusion 14-1 may be a flange provided to the second end 14 of the body 10. One end of the cover unit 20 may be connected to the protrusion 14-1.

The protrusion 14-1 may be formed in the shape of a ring, but embodiments are not limited thereto. That is, in other embodiments, a plurality of protrusions may be arranged on the outer circumferential surface and spaced apart from each other, and each of the protrusions may be connected to a corresponding one of the covers 20-1, 20-2, 20-3 and 20-4 of the cover unit 20.

The body 10 may be formed of quartz to prevent contamination of the raw material stored therein, but embodiments are not limited thereto.

The cover unit 20 may be formed in the shape of a plate having an opening 24 at the center thereof, and may be divided into a plurality of pieces. For example, the cover unit may be formed in the shape of a circular plate having a circular opening 24 at the center thereof, and may be divided into a plurality of covers 20-1 to 20-n (where, n is a natural number greater than 1). The covers 20-1 to 20-n (where, n is a natural number greater than 1) may be respectively connected to different sections of the protrusion 14-1.

The cover unit 20 may include a plurality of covers 20-1 to 20-n (where, n is a natural number greater than 1). The number of the covers 20-1 to 20-n (where, n is a natural number greater than 1) may be equal to or greater than 2.

Each of the covers 20-1 to 20-n (for example, n=4) may have one end connected to the second end 14 of the body 10, and may rotate about the one end, which is connected to the second end 14 to open or close the discharge port 15 in a hinged manner.

The length of each of the covers 20-1 to 20-n (for example, n=4) is less than half the diameter of the discharge port 15. Accordingly, when the discharge port 15 is closed by the covers 20-1 to 20-n (for example, n=4), the opening 24 may be defined at the center of the discharge port 15.

For example, when the discharge port 15 is closed by the covers 20-1 to 20-n (for example, n=4), the covers may form the shape of a plate or board having an opening 24 at the center thereof.

In FIG. 1, the covers 20-1 to 20-n (for example, n=4) may be set in a closed state to close the discharge port 15. In FIG. 2, the covers 20-1 to 20-n (for example, n=4) may be set in an opened state to open the discharge port 15.

While the opening 24 is illustrated in FIGS. 1 and 3 as having a circular shape, embodiments are not limited thereto. In other embodiments, the opening 24 may have an elliptical shape or a polygonal shape.

In FIGS. 1 to 3, the covers 20-1 to 20-n (for example, n=4) in the closed state, may form a shape of a circular plate having an opening 24 at the center thereof. However, the shape of the covers 20-1 to 20-n (for example, n=4) in the closed state may be determined by the shape of the discharge port 15. In other embodiments, the shape in the closed state may be elliptical or polygonal.

The covers 20-1 to 20-n (for example, n=4) may be spaced a certain distance from each other, and one end of each of the covers may be connected to the protrusion 14-1. At this time, the spacing distance among the covers 20-1 to 20-n (for example, n=4) may be less than the diameter of the mass of raw material to be stored in the recharging apparatus.

Each of the covers 20-1 to 20-n (for example, n=4) may include a cover plate and connection parts including a plurality of bolts and nuts.

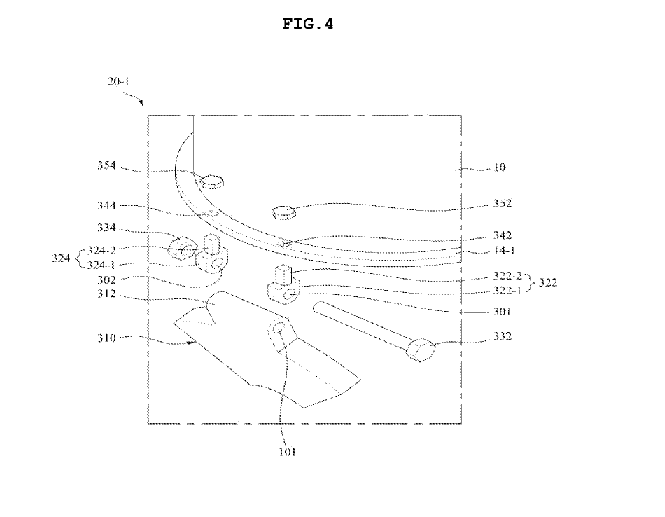

FIG. 4 is an exploded perspective view illustrating a first cover 20-1 in the dotted-line portion 11 of FIG. 2, and

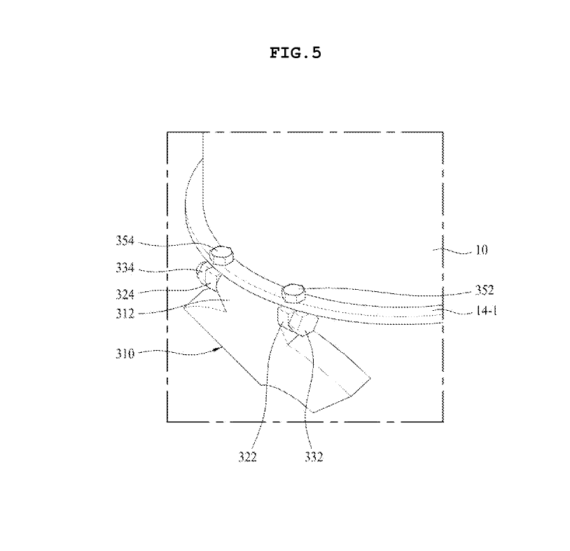

FIG. 5 is a perspective view illustrating assembly of the first cover 20-1 shown in FIG. 4. The structure of the second to fourth covers 20-2 to 20-4 may be the same as that of the first cover 20-1.

Referring to FIGS. 4 and 5, the first cover 20-1 may include a cover plate 310 and connection parts 322, 324, 332, 334, 352 and 354.

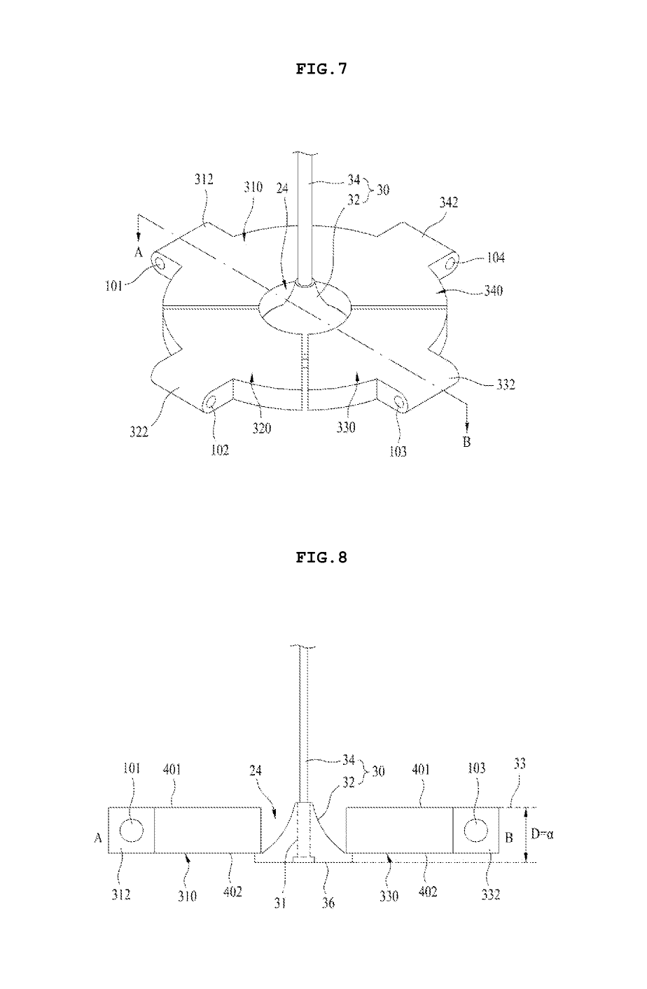

Each of the cover plates 310, 320, 330 and 340 (see FIG. 7) may have an extension part 312, 322, 332, 342 (see FIG. 7) extending from one end thereof, and a through hole 101, 102, 103, 104 penetrating two lateral surfaces of the extension part 312, 322, 332, 342 facing each other.

For example, the cover plate 310 may have an extension part 312 extending therefrom, and the extension part 312 may be provided with a through-hole 101 penetrating the extension part 312 in a horizontal direction. Herein, the horizontal direction may be the direction in which two lateral surface of the extension part 312 facing each other are passed through.

The connection parts 322, 324, 332, 334, 352 and 354 may connect the extension part 312 to the protrusion 14-1. The cover plate 310 may rotate about the connection parts 322, 324, 332, 334, 352 and 354.

For example, the connection parts 322, 324, 332, 334, 352 and 354 may include first and second fixing bolts 322 and 324, a connection bolt 332, and first to third nuts 334, 352 and 354.

The first fixing bolt 322 may include a first part 322-1 having a through-hole 301 and a second part 322-2 extending from the first part 322-1. The second fixing bolt 324 may include a first part 324-1 having a through-hole 302 and a second part 324-2 extending from the first part 324-1.

The second parts 322-2 and 324-2 may be formed in the shape of a polyhedron or a cross structure. The ends of the second parts 322-2 and 324-2 may be provided with threads to be coupled to the second and third nuts.

The first fixing bolt 322 may be positioned at one side of the extension part 312, and the second fixing bolt 324 may be positioned at another side of the extension part 312.

The connection bolt 332 may be connected to a first nut 334 through the through-hole 301 of the first fixing bolt 322, the through-hole 101 of the extension part 312, and the through-hole 302 of the second fixing bolt 324.

That is, the connection bolt 332 may interconnect the first and second fixing bolts 322 and 324 and the extension part 312, and the cover plate 310 may rotate about the connection bolt 332.

The protrusion 14-1 may have a plurality of through holes (e.g., 342 and 344) allowing the second parts 322-2 and 324-2 of the first and second fixing bolts 322 and 324 to be inserted thereinto.

The shape of the cross sections of the through holes (e.g., 342 and 344) may be determined by the shape of the second parts 322-2 and 324-2. For example, the shape of the cross sections of the through holes (e.g., 342 and 344) may be a triangle, a rectangle, or a cross such that the second parts 322-2 and 324-2 are inserted thereinto.

The second part 322-2 of the first fixing bolt 322 may pass through the through hole 342 formed in the protrusion 14-1. The end of the second part 322-2 having passed through the through hole 342 may be coupled to the second nut 352.

The second part 324-2 of the second fixing bolt 324 may pass through the through hole 344 formed in the protrusion 14-1. The end of the second part 324-2 having passed through the through hole 342 may be coupled to the third nut 354.

By the first and second fixing bolts 322 and 324 and the second and third nuts 352 and 354, the cover plate 310 may be fixed to the protrusion 14-1.

Since the first and second fixing bolts 322 and 324 at both sides of the extension part 312 support the cover plate 310, and the second parts 322-2 and 324-2 of the first and second fixing bolts 322 and 324 have a polygonal or cross-shaped cross section rather and a circular cross section, the cover plate 310 may be prevented from rotating about the first and second fixing bolts 322 and 324.

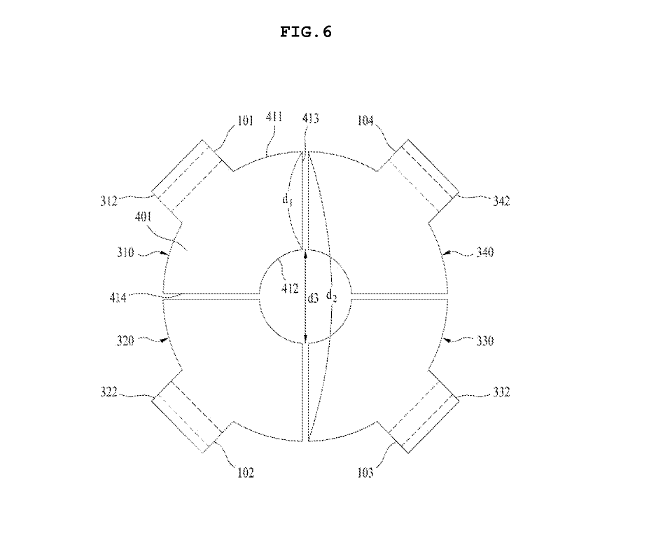

FIG. 6 is a plan view illustrating a plurality of cover plates 310 to 340 shown in FIG. 3.

Referring to FIGS. 3 and 6, each of the cover plates 310 to 340 may include an upper surface 401 (see FIG. 4), a lower surface 402 (see FIG. 3), and a plurality of lateral surfaces 411, 412, 413 and 414 positioned between and the upper surface 401 and the lower surface 402.

When closed (see FIG. 7), the cover plates 310 to 340 may form the shape of a circular plate having an opening 24 at the center thereof. Each of the cover plates 310 to 340 may have an extension part 312, 322, 332, 342 protruding from a first lateral surface 411 of the lateral surfaces 411, 412, 413 and 414.

The extension part 312, 322, 332, 342 may protrude from one region of the first lateral surface 411 in a first direction. The extension parts 312, 322, 332 and 342 may respectively have the through holes 101 to 104. The first lateral surface 411 may be a curved surface. Herein, the first direction may be a direction extending from the second lateral surface 412 to the first lateral surface 411.

For example, the first lateral surface 411 may be a curved surface having the same curvature as the inner circumferential surface of the cylindrical body 10, but embodiments are not limited thereto.

The third lateral surface 413 and the fourth lateral surface 414 positioned between the first lateral surface 411 and the second lateral surface 412 may face the third lateral surface 413 and the fourth lateral surface 414 of a neighboring cover plate 320 or 340.

The second lateral surface 412 facing the first lateral surface 411 may be a concavely curved surface, but embodiments are not limited thereto. Since the second lateral surface 412 is a portion that contacts a supporting cone 32, the concavely curved surface may closely contact the supporting cone 32.

Since the diameter or length d1 of each of the cover plates 310, 320, 330 and 340 is less than half the diameter of the discharge port 15, the second lateral surfaces 412 of the cover plates 310, 320, 330 and 340 may form the opening 24 when the discharge port 15 is closed by the cover plates 20-1 to 20-n (for example, n=4). At this time, since the second lateral surface 412 is a concavely curved surface, the opening 24 may have a circular shape. However, embodiments are not limited thereto.

The cover plates 310, 320, 330 and 340 may cover a portion of the discharge port 15, and the supporting cone 32, which will be described later, may cover the opening 24.

For example, the ratio of the diameter d1 of each of the cover plates 310, 320, 330 and 340 to the diameter d2 of the discharge port 15 (d1:d2) may be 1:2.5 to 4. The ratio of the diameter d3 of the opening 24 to the diameter d2 of the discharge port 15 (d3:d2) may be 1:2 to 5. In addition, the ratio of the diameter d4 of the supporting cone 32 to the diameter d2 of the discharge port 15 (d4:d2) may be 1:2 to 5.

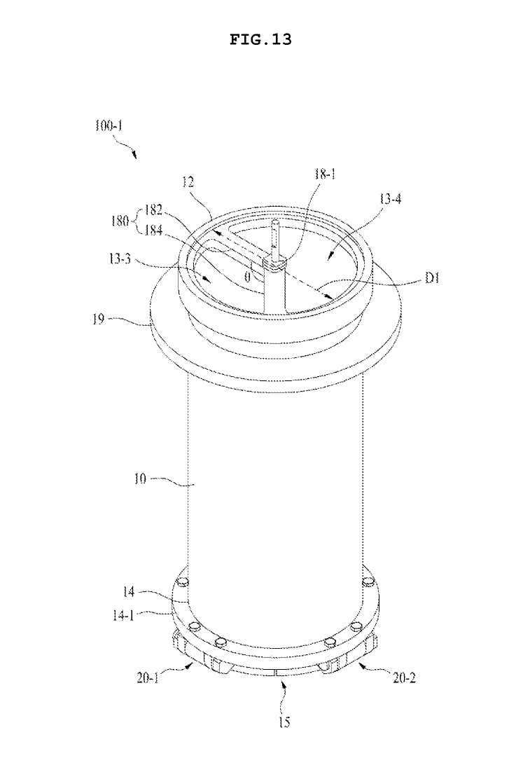

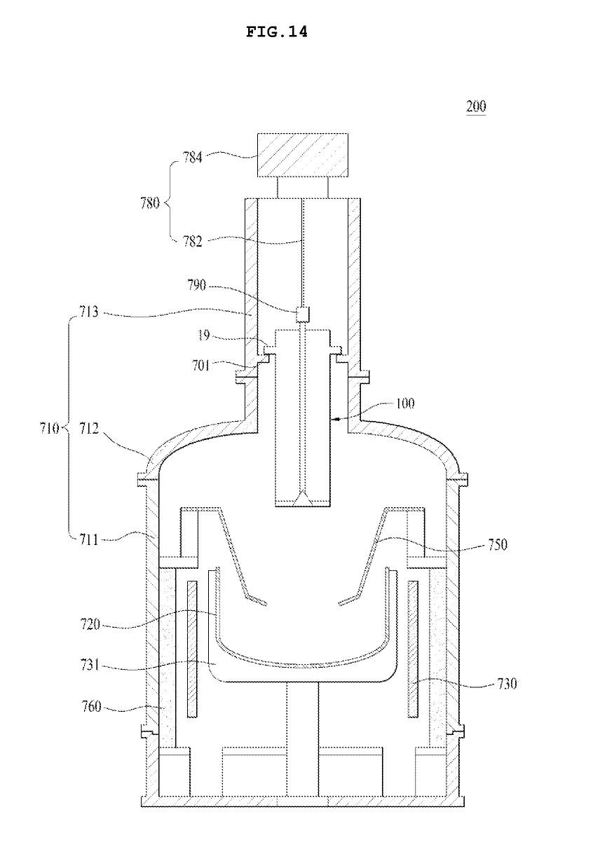

FIG. 11 is a view illustrating covers 21-1 and 21-2 according to another embodiment, and FIG. 12 is a view illustrating cover plates 410 and 420 of the covers 21-1 and 21-2 shown in FIG. 1.

Referring to FIGS. 11 and 12, the embodiment shown in FIG. 11 may include two covers 21-1 and 21-2, in contrast with the previous embodiment shown in FIG. 1, which includes four covers 20-1 to 20-4.

The first and second covers 21-1 and 21-2 may be spaced a certain distance apart from each other, and one end of each of the first and second covers 21-1 and 21-2 may be connected to the protrusion 14-1. Each of the first and second covers 21-1 and 21-2 may include a cover plate 410, 420 and a plurality of bolts and nuts. The bolts and nuts included in the first and second covers 21-1 and 21-2 may have the same structure as the structure described in FIG. 4, and thus a description thereof will be omitted.

The cover plates 410 and 420 may be two segments of a circular plate, and may have an identical or symmetrical shape.

Each of the cover plates 410 and 420 may include an upper surface, a lower surface, and a plurality of lateral surfaces 511, 512, 513 and 514 positioned between the upper surface and the lower surface.

When closed, the cover plates 410 and 420 may form the shape of a circular plate having an opening 24 at the center thereof. Each of the cover plates 410 and 420 may have an extension part 410-1 or 410-2 protruding from one region of a first lateral surface 511 of the lateral surfaces. The extension part 410-1 or 410-2 may have a through hole 101-1 or 101-2. The first lateral surface 511 may be a curved surface. Herein, the first direction may be a direction extending from the second lateral surface 512 to the first lateral surface 511.

The third lateral surface 513 and the fourth lateral surface 514 positioned between the first lateral surface 511 and the second lateral surface 512 of the first cover plate 410 may respectively face the third lateral surface and the fourth lateral surface of the second cover plate 420. The second lateral surface 512 may be a concavely curved surface, but embodiments are not limited thereto. Since the second lateral surface 512 is a portion that contacts a supporting cone 32, the concavely curved surface may closely contact the supporting cone 32.

The opening and closing adjuster 30 may support each of the cover plates 310, 320, 330 and 340, and rotate the cover plates 410 and 420 through vertical movement. As the cover plates 410 and 420 rotate, the discharge port 15 may be opened or closed.

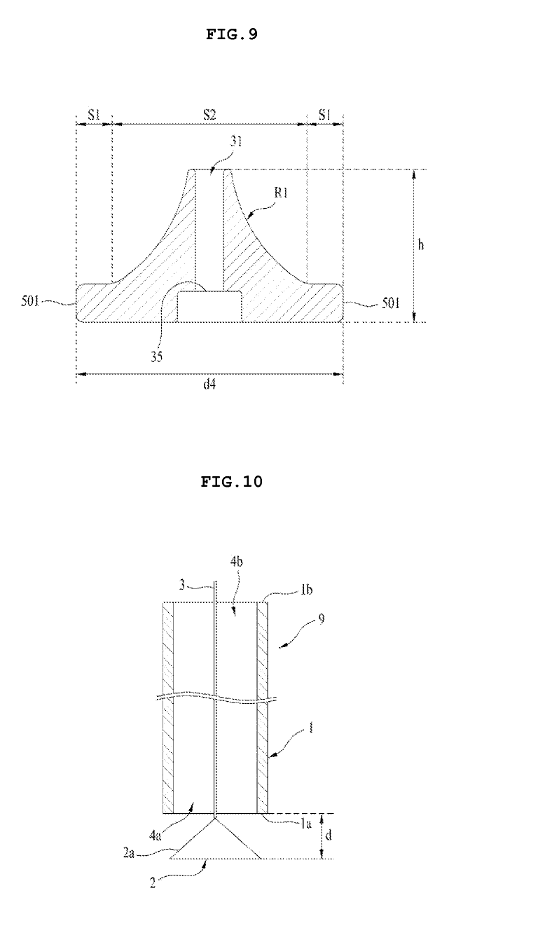

FIG. 7 is a perspective view illustrating an opening and closing adjuster 30 that supports the cover plates 310, 320, 330 and 340 shown in FIG. 3, and FIG. 8 is a cross-sectional view illustrating the cover plates and opening and closing adjuster of FIG. 7, taken along line AB in FIG. 7. FIG. 7 is a perspective view showing the cover plates 310, 320, 330 and 340 that completely close the discharge port 15.

Referring to FIGS. 7 and 8, the opening and closing adjuster 30 includes a supporting cone 32 to support one region of the lower surface 402 of each of the cover plates 310, 320, 330 and 340, and a supporter 34 having one end connected to the supporting cone 32 and the other end connected to an external lifting means 780 (see FIG. 14).

The supporting cone 32 may have a shape of a cone having a central portion protruding farther than the peripheral portion thereof, and may be formed of quartz to prevent contamination of the raw material. The supporter 34 may have a rod shape, and may be formed of molybdenum (Mo).

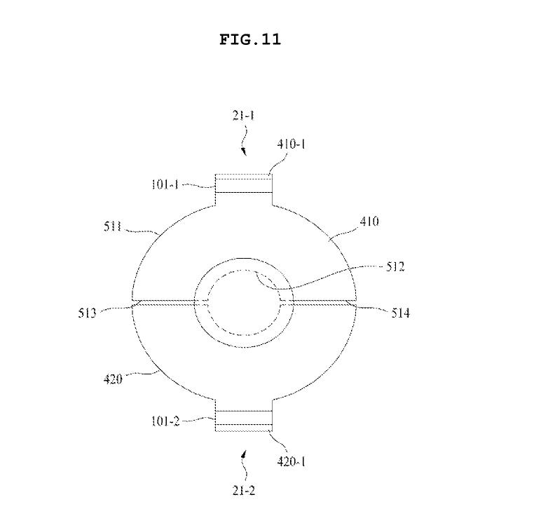

FIG. 9 is an enlarged view illustrating the supporting cone 32 shown in FIG. 7.

Referring to FIG. 9, the supporting cone 32 may include a first portion S1 forming a peripheral region of the supporting cone 32 spanning a certain distance from the lower lateral surface 501, and a second portion S2 forming the remaining region other than the first portion S1, positioned at the center of the supporting cone 32.

Referring to FIG. 8, the first portion S1 may support the parts of the cover plates 310, 320, 330 and 340 that are adjacent to the second lateral surface 412. The first portion S1 may be formed to be flat to stably support the cover plates 310, 320, 330 and 340.

The second portion S2 may be formed at the center of the supporting cone 32 in the shape of raised cone. The outer circumferential surface of the second portion S2 may be a curved surface having a constant curvature R1. For example, the curvature R1 of the second portion S2 may be identical to the curvature of a circle whose radius is between 55 mm and 65 mm.

When the cover plates 310, 320, 330 and 340 rotate, friction may occur between the edge portions or corner portions of the cover plates 310, 320, 330 and 340 and the second portion S2. In this embodiment, the second portion S2 may have a curved surface with a constant curvature, thereby preventing damage to the supporting cone 32 due to friction.

The supporting cone 32 may allow the supporter 34 to be inserted into the center thereof, and may be provided with a groove 31 exposing the bottom. One end of the supporter 34 may be inserted into the groove 31 and joined to the bottom of the supporting cone 32.

For example, a threaded groove 35 may be formed at the bottom of the groove 31 of the supporting cone 32, and one end of the supporter 34 may be provided with threads to be coupled to the threaded groove 35. One end of the supporter 34 may be inserted into the groove 31. Once inserted, the one end of the supporter 34 may be coupled with the threaded groove 35 formed in the groove 31.

The other end of the supporter 34 may be connected to an external lifting means 780 (see FIG. 14) by passing through the through-hole 18-1 of the guiding part 18 described above.

The guiding part 18 may facilitate vertical movement of the supporter 34 and guide the supporter 34 such that the supporter 34 is aligned with the center of the opening 24. In addition, during vertical movement of the supporter 34, the guiding part 18 may function to prevent lateral rocking of the supporter 34.

The supporting cone 32 connected to the supporter 34 may be moved by the external lifting means 780 (see FIG. 14), and the cover plates 310, 320, 330 and 340 supported by the supporting cone 32 may rotate about the axis of rotation according to movement of the supporting cone 32. As described above, the axis of rotation may be the connection part that connects the protrusion 14-1 to one end of the cover plate 310, 320, 330, 340, more specifically, the connection bolt 332 shown in FIG. 4. The structure of the connection part is not limited to the structure shown in FIG. 4, and any structure that is rotatable when connected may be employed.

The opening and closing adjuster 30 may adjust the rotational angle of the respective cover plates 310, 320, 330 and 340 by adjusting the distance between the reference horizontal plane 33 and the lowest end 36 of the supporting cone 32. Herein, the reference horizontal plane 33 may be a plane which is parallel with the second end 14 of the body 10 and positioned at the same level as the second end 14.

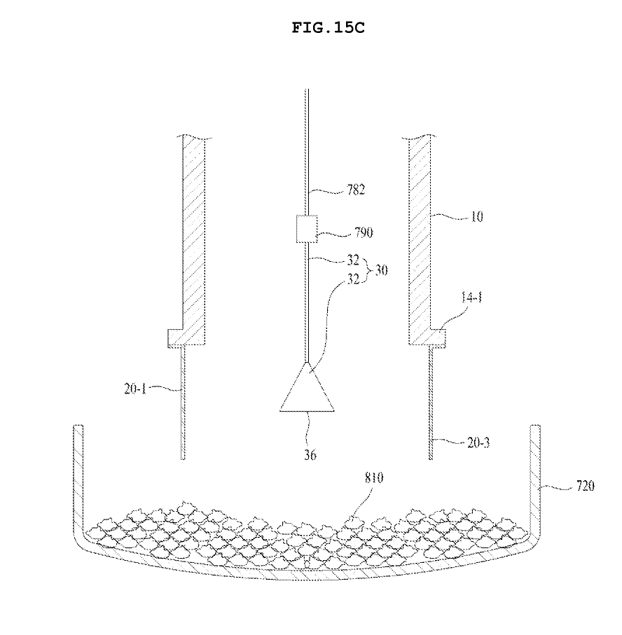

FIGS. 15a to 15c are views illustrating filling the crucible 720 (see FIG. 14) with a raw material using a recharging apparatus 100 according to an embodiment.

Referring to FIG. 15a, the distance D between the lowest end 36 of the supporting cone 32 and the reference horizontal plane 33 is adjusted such that the covers 20-1 to 20-4 completely close the discharge port 15 as shown in FIG. 8.

For example, when the discharge port 15 is completely closed by the covers 20-1 to 20-4, the distance D between the reference horizontal plane 33 and the lowest end 36 of the supporting cone 32 may be α. In the case that the distance D between the reference horizontal plane 33 and the lowest end 36 of the supporting cone 32 is α, the angle by which the cover plates 310, 320, 330 and 340 have rotated with respect to the reference horizontal plane 33 may be 0°. At this time, the discharge port 15 may be closed by the cover plates 310, 320, 330 and 340 and the second region S2 of the supporting cone 32.

While the discharge port 15 is completely closed by the covers 20-1 to 20-4, the interior of the body 10 is filled with a raw material 810 (e.g., a polycrystalline mass) supplied through the introduction ports 13-1 and 13-2.

After the body 10 is filled with the raw material 810, the recharging apparatus 100 may be lowered into the chamber 710 by the lifting means 780.

The stopping projection 19 of the recharging apparatus 100 that is lowered may be stopped by a support projection 701 provided inside the chamber 710, and thus lowering of the body 10 of the recharging apparatus 100 may be stopped by the support projection 701.

The distance D between the reference horizontal plane 33 and the lowest end 36 of the supporting cone 32 before the stopping projection 19 is stopped by the support projection 701 may be α.

Referring to FIG. 15b, after the body 10 is interrupted and stopped by the support projection 701, the opening and closing adjuster 30 is lowered by the lifting means 780. Thereby, the covers 20-1 to 20-4 are allowed to rotate. According to rotational movement of the covers 20-1 to 20-4, the discharge port 15 may be gradually opened. As the rotational angle of the covers 20-1 to 20-4 increases, the degree of opening of the discharge port 15 may increase.

As the opening and closing adjuster 30 is lowered, the distance D between the reference horizontal plane 33 and the lowest end 36 of the supporting cone 32 may become greater than α, and rotational angle of the cover plates 310, 320, 330 and 340 with respect to the reference horizontal plane 33 may increase. At this time, the discharge port 15 may be partially closed and partially opened by the cover plates 310, 320, 330 and 340 and the second region S2 of the supporting cone 32.

The minimum distance D between the reference horizontal plane 33 and the lowest end 36 of the supporting cone that may allow smooth discharge of the mass of the polycrystalline raw material 810 may be β.

As the supporting cone 32 is lowered from the position shown in FIG. 8, the discharge port 15 is gradually opened. The minimum distance between the reference horizontal plane 33 and the lowest end 36 of the supporting cone 32 allowing smooth discharge of the raw material 810 may be defined as the open distance D of the discharge port 15.

The size of the polycrystalline mass 810 (for example, a polysilicon mass), the raw material filling the recharging apparatus 100, may be equal to or less than 100 mm, for example, between 0.5 mm and 100 mm.

The polycrystalline mass 810 (for example, a mass of polysilicon) may be classified according to the size thereof. For example, a polycrystalline mass whose diameter is less than mm may be defined as a first polycrystalline mass (also, referred to as a chip poly), and a polycrystalline mass whose diameter is equal to or greater than 50 mm (for example, between mm and 100 mm) may be defined as a second polycrystalline mass (also, referred to as a nugget poly). Herein, the diameter of the polycrystalline mass may the maximum diameter of the polycrystalline mass.

Referring to FIG. 15c, when the opening and closing adjuster 30 is further lowered, and the supporting cone 32 is spaced apart from the lower surface of the cover plates 310, 320, 330 and 340, the angle by which the cover plates 310, 320, 330 and 340 rotate with respect to the reference horizontal plane 33 may be 90°. At this time, the discharge port 15 may be completely opened.

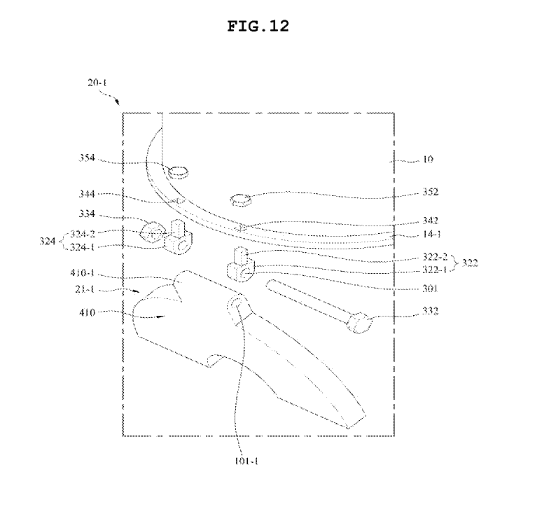

FIG. 10 is a cross-sectional view illustrating a typical recharging apparatus 9.

Referring to FIG. 10, the recharging apparatus 9 may include a main body 1 open at both ends 1a and 1b thereof, a lead body 2 formed in a conical shape to open and close one end of the main body 1, and a wire 3 connected to the lead body 2. The lower end 1a of the main body 1 may be provided with an introduction port 4b, and the upper end 1b of the main body 1 may be provided with a discharge port 4a.

The length d from the lower end 1a of the main body 1 to the lower end of the lead body 2 (hereinafter, referred to as “open length”) allowing smooth discharge of the polycrystalline mass from the recharging apparatus 9 to the discharge port 4a may be determined by the diameter of the polycrystalline mass. For example, as the diameter of the polycrystalline mass increases, the open length d of the recharging apparatus 9 may increase.

For example, when the diameter of the main body 1 is 230 mm, the open length d for the chip poly may be 80 mm, and the open length d for the nugget poly may be 120 mm.

The processes for growing a raw material (e.g., silicon) using the recharging apparatus 9 may include a raw material melting process, an additional charging process of additional charging with the raw material using the recharging apparatus, and a crystal growing process, which are undergone in this order.

Herein, the additional charge process is undergone to increase the amount of the molten liquid by additionally charging with the raw material since the level of the surface of the molten liquid in the crucible may be greatly lowered due to variation in size of the raw material when the crucible is charged with the initial raw material and the charged raw material is molten.

In the additional charge process, the surface of molten liquid may be raised to the level near the upper end of the crucible. Accordingly, in the case that the open length d of the recharging apparatus 9 increases according to use of the nugget poly having a larger diameter, the lead body 2 may have a risk of touching the molten liquid in the crucible or constituents therearound (e.g., a heat shield unit and a scale rod). Thereby, the recharging apparatus 9 may be contaminated, or the constituents around the recharging apparatus 9 may be damaged.

In the case that a chip poly having a smaller size is used, the events as above may be prevented from occurring. However, the chip poly undergoes more processes than the nugget poly, and therefore manufacturing costs may increase.

Since the lead body 2 shown in FIG. 10 needs to cover the entire discharge port 4a, the diameter of the lower end of the lead body 2 needs to be equal to that of the discharge port 4a.

However, in the illustrated embodiment, the diameter of the opening 24 defined by the cover unit 20 is less than that of the discharge port 15. Therefore, the discharge port 15 may be opened or closed by using the supporting cone 32 having relatively small dimensions (e.g., the height h and diameter d4) compared to the case of FIG. 10.

Since the illustrated embodiment uses the supporting cone 32 having a small size to open or close the discharge port 15, the open distance β (see FIG. 15b) for smooth discharge of the nugget poly may be shortened.

For example, when the supporting cone 32 is lowered even by 10 mm to 20 mm from the position shown in FIG. 8, the nugget poly may be smoothly discharged.

Accordingly, the illustrated embodiment may prevent contamination of the recharging apparatus 100 and damage the constituents of the growth apparatus positioned around the recharging apparatus 100 by shortening the distance by which the supporting cone 32 is lowered to allow smooth discharge of the nugget poly.

In addition, according to the embodiment, the cover unit 20 rotates about the protrusion 14-1, and thus the molten liquid may be prevented from splashed out of the crucible by the dropped raw material.

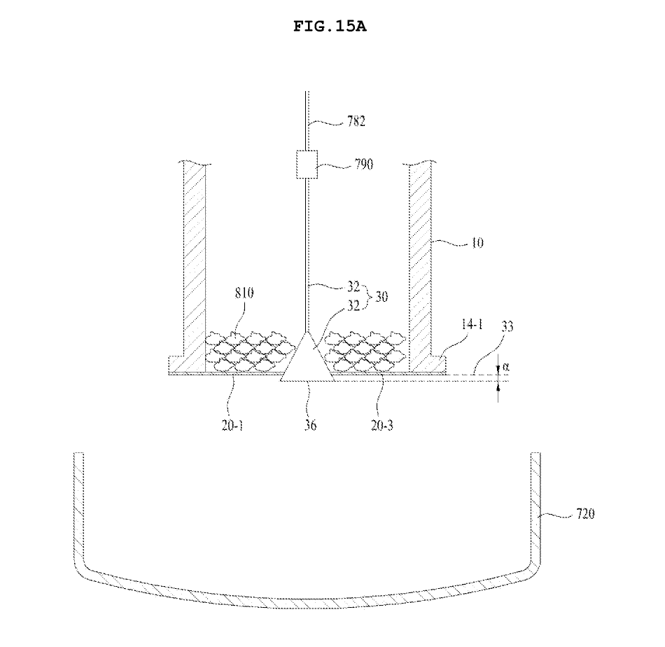

FIG. 13 is a perspective view illustrating a recharging apparatus 100-1 according to another embodiment. Reference numerals identical to those in FIG. 1 represent identical constituents. A description of the identical constituents will be briefly given or omitted.

Referring to FIG. 13, a guiding part 180 of the recharging apparatus 100-1 is curved at the center thereof, in contrast with the guiding part 18 of FIG. 1 which has the shape of a straight line or a line.

The guiding part 180 may include a first part 182 positioned at one side of the through-hole 18-1 positioned at the center of the guiding part 180, and a second part 184 positioned at the other side of the through-hole 18-1. The first part 182 and the second part 184 of the guiding part 180 may form a structure bent at the position of the through-hole 18-1.

One end of the first part 182 may be connected to one region of the first end 12, and the other end thereof may be connected to one end of the second part 184. The other end of the second part 184 may be connected to the other region of the first end 12.

A first introduction port 13-3 and a second introduction port 13-4 may be distinguished from each other by the first part 182 and the second part 184. Since the guiding part 180 is formed to be bent at the center thereof, the size of the first introduction port is different from that of the second introduction port. That is, the first introduction port 13-3 is smaller than the second introduction port 13-4.

In filling the recharging apparatus with raw material, the body may be easily filled with the raw material when the body is inclined and a majority of the mass of the raw material is introduced through one of the two introduction ports which is at a lower location.

The number of the introduction ports may be 2, but only one of the introduction ports may substantially be used for convenience since the body is inclined when in use. By allowing the introduction port that is used to have a greater size than the introduction port that is not used, the raw material may be introduced more easily and quickly into the recharging apparatus.

However, in the case that the angle between the first part 182 and the second part 184 is too large, the guiding part 180 that guides the supporter 34 may have a risk of being damaged or broken.

The angle θ formed by the first part 182 and the second part 184 may be greater than 90° and less than 180°. The angle θ formed by the first part 182 and the second part 184 may be between 120° and 160°.

To ensure smooth introduction of the mass of the raw material, the diameter d1 of the first end 12 may be between 230 mm and 260 mm.

Therefore, according to this embodiment, the body 10 may be more quickly and more easily filled with the mass of a raw material than in the previous embodiment shown in FIG. 1.

FIG. 14 is a cross-sectional view illustrating a single crystal growth apparatus 200 including a recharging apparatus 100 according to an embodiment.

Referring to FIG. 14, the single crystal growth apparatus 200 may include a chamber 710, a crucible 720, a heating element 730, a crucible supporter 731, a heat shield member 750, an insulation material 760, and a lifting means 780.

According to the position of coupling of the chamber 710, the chamber 710 may include a body chamber 711, a dome chamber 712, and a pull chamber 713.

The crucible 720 may be installed in the body chamber 711, and the dome chamber 712 may form a cover part at the upper end of the body chamber 711. The body chamber 711 and the dome chamber 712, which provide an environment in which a single crystal silicon ingot is grown from polycrystalline silicon, may have the shape of a cylinder having accommodation space therein. The pull chamber 713 is positioned at the upper end of the dome chamber 712, and may form a space where the grown single crystal silicon ingot.

The chamber 710 may have a support projection 701 protruding from the inner wall of the chamber 710 in a horizontal direction. For example, the support projection 701 may protrude from the inner wall of the pull chamber 713 in a horizontal direction. The support projection 701 may support the stopping projection 19 of the recharging apparatus 100.

Once the stopping projection 19 of the recharging apparatus 100 is supported by the support projection 701 of the chamber 710, the body 10 of the recharging apparatus 100 is not lowered any more but is stopped even when the opening and closing adjuster 30 is lowered by the lifting means 780.

The recharging apparatus 100 is stopped by the support projection 701, and the covers 20-1 to 20-4 rotate according to lowering of the opening and closing adjuster 30. Thereby, the discharge port 15 may be gradually opened.

The crucible 720 may be disposed inside the body chamber 711, and the crucible supporter 731 may be positioned below the crucible 720 to support the crucible 720. The heating element 730 may be disposed in the body chamber 711 to be spaced apart from the outer circumferential surface of the crucible 720.

The insulation material 760 may be installed between the heating element 730 and the inner wall of the body chamber 711, and may block leakage of heat from the heating element 730 to the exterior of the body chamber 711.

The lifting means 780 may include a fixing part 782 to fix and support a growing object or the recharging apparatus 100, and a lifting part 784 to raise or lower a grown object (e.g., the single crystal ingot) or the opening and closing adjuster 30 of the recharging apparatus 100.

The fixing part 782 may be of a cable type or a shaft type, and one end thereof may be provided with a seed chuck. The lifting part 784 may raise or lower the recharging apparatus 100 or the grown object connected to the fixing part 782 using a motor.

A seed may be connected to the seed chuck for growth of single crystals.

To supply a raw material to the single crystal growth apparatus 200, the recharging apparatus 100 may be connected to the seed chuck. For example, the supporter 34 of the opening and closing adjuster 30 may be connected to the seed chuck, and the opening and closing adjuster 30 connected to the seed chuck may be raised or lowered by the lifting part 784. By raising or lowering the opening and closing adjuster 30, the cover unit 20 may open or close the discharge port 15.

As is apparent from the above description, embodiments may prevent contamination by the molten liquid and damage to constituents positioned around a recharging apparatus.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A recharging apparatus comprising:
a body provided with an introduction port and a discharge port;
a cover unit comprising a plurality of divided covers, each of the covers being connected to one end of the body and adapted to rotated about the one end of the body; and
an opening and closing adjuster to support one surface of each of the covers and to rotate each of the covers about a portion of each of the covers connected to the one end of the body.

2. The recharging apparatus according to claim 1, wherein the cover unit is formed in a shape of a plate having an opening at a center thereof, the covers being formed by dividing the plate having the opening at the center thereof into at least two pieces.

3. The recharging apparatus according to claim 1, wherein an outer circumferential surface of the one end of the body is provided with a protrusion, and each of the covers is connected to the protrusion.

4. The recharging apparatus according to claim 3, wherein each of the covers comprises:
a cover plate provided with an upper surface, a lower surface, a plurality of lateral surfaces positioned between the upper surface and the lower surface, and an extension part protruding from one of the lateral surfaces; and
a connection part to connect the extension part to the protrusion.

5. The recharging apparatus according to claim 4, wherein the connection part comprises:
first to third nuts;
a first fixing bolt provided with one end having a first through hole and the other end coupled to a first nut by penetrating the protrusion;
a second fixing bolt provided with one end having a second through hole and the other end coupled to a second nut by penetrating the protrusion; and
a connection bolt coupled to a third nut by passing through the first through hole, the extension part, and the second through hole,
wherein the cover plate rotates about the connection bolt.

6. The recharging apparatus according to claim 5, wherein a cross section of each of the first fixing bolt and the second fixing bolt penetrating the protrusion has a shape of a polygon or a cross.

7. The recharging apparatus according to claim 4, wherein the opening and closing adjuster comprises:
a supporting cone to support one region of the lower surface of each of the cover plates; and
a supporter connected to an upper end of the supporting cone, the supporter supporting the supporting cone.

8. The recharging apparatus according to claim 7, wherein a rotational angle of the cover plates is adjusted by vertical movement of the supporting cone.

9. The recharging apparatus according to claim 7, wherein the supporting cone is provided, at a center thereof, with a groove allowing the supporter to be inserted thereinto,
wherein one end of the support inserted into the groove is coupled to a bottom of the supporting cone.

10. The recharging apparatus according to claim 1, wherein an outer circumferential surface of the body adjacent to the introduction port is provided with an interruption projection protruding in a horizontal direction.

11. The recharging apparatus according to claim 7, further comprising a guiding part extending in a diametrical direction of the body, having both ends fixed to two different regions of the body adjacent to the introduction port, and provided with a through hole allowing the supporter to be inserted thereinto.

12. The recharging apparatus according to claim 1, wherein a material to fill the body is a polycrystalline mass having a diameter ranging from 0.5 mm to 100 mm.

13. A recharging apparatus comprising:
a body comprising an introduction port, a discharge port, and a hollow penetrated portion arranged between the introduction port and the discharge port;
a cover unit comprising a plurality of covers, each of the covers being connected to one end of the body adjacent to the discharge port; and
an opening and closing adjuster to support each of the covers and to rotate each of the covers to open and close the discharge port.

14. The recharging apparatus according to claim 13, wherein, when the covers close the discharge port, the covers form a shape of a plate divided into a plurality of pieces and having an opening at a center thereof.

15. The recharging apparatus according to claim 13, wherein the opening and closing adjuster comprises:
a supporting cone to support one region of a lower surface of each of the covers; and
a supporter connected to an upper end of the supporting cone, the supporter supporting the supporting cone.

16. The recharging apparatus according to claim 15, wherein each of the covers is rotated about a portion thereof connected to the body by vertical movement of the supporting cone.

17. The recharging apparatus according to claim 15, further comprising a guiding part extending in a diametrical direction of the body, having both ends fixed to two different regions of the body adjacent to the introduction port, and provided with a through hole allowing the supporter to be inserted thereinto.

18. The recharging apparatus according to claim 17, wherein the guiding part is formed to be bent, the introduction port is divided into a first introduction port and a second introduction port by the bent guiding part, and a size of the first introduction port is different from a size of a second introduction port.

19. A growth apparatus comprising:
a chamber provided with a support projection protruding from an inner wall of the chamber in a horizontal direction;
a crucible positioned in the chamber;
a recharging apparatus to store a raw material and to supplied the stored raw material to the crucible; and
a lifting means to vertically move the recharging apparatus within the chamber,
wherein the recharging apparatus comprises:
a body comprising an introduction port, a discharge port, and a stopping projection formed on an outer circumferential surface of the body adjacent to the introduction port and stopped and supported by the support projection;
a cover unit including a plurality of divided covers, each of the covers being connected to one end of the body;
a supporting cone to support a lower surface of each of the covers; and
a supporter having one end connected to an upper end of the supporting cone, and the other end connected to the lifting means.

20. The growth apparatus according to claim 19, wherein the covers rotate about one end of the body after the stopping projection of the recharging apparatus is stopped and supported by the support projection of the chamber.
